(19) United States
(12) Patent Application Publication
(10) Pub. No.: US 2005/0000414 A1
(43) Pub. Date: Jan. 6, 2005

(54) Method and apparatus for applying conductive ink onto semiconductor substrates

(75) Inventors: Jerome S. Culik, Nottingham, PA (US); Shawn P. Riley, Wilmington, DE (US); Frank R. Faller, Freiberg, DE (US); Kevin W. Allison, Goleta, CA (US)

Correspondence Address: BURR & BROWN, PO BOX 7068, SYRACUSE, NY, 13261-7068, US

(73) Assignee: ASTROPOWER, INC., Newark, DE (US)

(21) Appl. No.: 10/764,817

(22) Filed: Jan. 26, 2004

Related U.S. Application Data
(63) Continuation of application No. PCT/US02/23731, filed on Jul. 26, 2002.
(60) Provisional application No. 60/308,378, filed on Jul. 27, 2001.
(60) Provisional application No. 60/338,353, filed on Dec. 6, 2001.

(51) Int. Cl. B05C 1/00; B05D 5/00; H01L 21/20; H01L 21/44

(52) U.S. Cl. 118/200; 118/216; 118/244; 427/256; 438/584; 438/674

(57) ABSTRACT

A method and apparatus for applying contacts to a semiconductor substrate, comprising one or more applicator rolls. Each applicator roll comprises a printing surface which has at least one raised pattern surface. Each raised first pattern surface is positioned such that upon rotation of the first rotatable applicator roll, it passes through a printing space. As a result, a surface of a semiconductor substrate passing through the printing space while the raised pattern surface(s) is covered with a conductive ink and the applicator roll is being rotated comes into contact with the conductive ink on at least part of the raised pattern surface, and does not come into contact with conductive ink on substantially any of the printing surface other than the raised pattern surface. Accordingly, a conductive ink pattern is deposited on the semiconductor substrate surface. In a preferred aspect, the conductive ink is a hot melt ink.

### CROSS-REFERENCE TO RELATED APPLICATIONS

This application claims the benefit of U.S. Provisional Patent Application No. 60/308,378, filed Jul. 27, 2001, the entirety of which is incorporated herein by reference. This application also claims the benefit of U.S. Provisional Patent Application No. 60/338,353, filed Dec. 6, 2001, the entirety of which is incorporated herein by reference.

### FIELD OF THE INVENTION

The present invention is directed to an apparatus for applying one or more conductive contacts to a semiconductor substrate. In particular, the present invention is directed to an apparatus for applying a conductive contact to one side of a diode to be used in a solar-electric cell. The present invention is further directed to an apparatus for applying a conductive contact to one surface of a semiconductor diode to be used in a solar-electric cell, and also applying a second conductive contact to an opposite surface of the semiconductor diode.

The present invention is further directed to a method for applying one or more conductive contacts to a semiconductor substrate as discussed above.

### BACKGROUND OF THE INVENTION

Solar-electric systems have become more and more common, and of greater and greater importance. The use of solar-electric systems is expected to increase, potentially dramatically. As such, improvements in solar-electric technology, even incremental improvements, are of great importance.

Solar-electric systems derive their energy from photovoltaic cells (referred to herein as “PV cells”). Typically, a plurality of PV cells are electrically connected in a suitable pattern. A wide variety of types of PV cells are known. For example, a representative PV cell of “layered construction” includes a semiconductor substrate (e.g., formed of silicon, germanium, or gallium arsenide, etc.) having at least one n-type region (i.e., at least one region which is doped with an n-type dopant), at least one p-type region (e.g., at least one region which is doped with a p-type dopant), at least one n-contact electrically connected to the at least one n-type region and at least one p-contact electrically connected to the at least one p-type region. Such layered PV cells also typically include a cover (e.g., made of glass) and one or more anti-reflective coatings. Typically, a plurality of PV cells are encased in a glass cover to form a PV module, which is mounted in any suitable way in or on a frame.

It has been found that various materials can effectively be employed to form the n-contact and various materials can effectively be employed to form the p-contact. Such materials include metals and conductive ceramic materials. For example, it has been found that one example of a suitable contact is a metallized aluminum layer, and in cases where the semiconductor substrate is, e.g., single crystal silicon, during deposition of the aluminum, some of the aluminum forms an alloy with silicon, which results in an increase in the voltage of the current produced by the PV cell. It has also been recognized that silver provides better soldering properties than does aluminum. Also, it has been observed that silver does not bond strongly to aluminum or to aluminum oxide. Accordingly, one type of design of a contact has included regions of aluminum as well as regions of silver. Where the semiconductor substrate is single crystal silicon, the larger the area of silver, the smaller the voltage increase provided by the aluminum; also, in view of the higher cost of silver, the larger the area of silver, the larger the overall cost of the contact. As a result, a variety of contacts have been used, e.g., contacts having different patterns of aluminum and silver regions which seek to minimize the size of the region or regions containing silver and to maximize the size of the region or regions containing aluminum.

Conventionally, semiconductor substrate contacts have been applied to semiconductor substrates using screenprinting. As discussed below, there are a number of limitations and a number of drawbacks inherent in use of screenprinting to apply semiconductor substrate contacts.

Screenprinting techniques are well known. For example, in a typical screenprinting technique for applying a printing ink to a print surface, a screenprinter includes a screen mounted on a frame, the screen having a negative areas (i.e., areas in a pattern which covers areas in which printing does not occur, so that printing does occur in positive areas defined by areas where the negative pattern is not present) formed of a blocking material formed, e.g., of an emulsion. One surface of the screen is placed on the print surface, and (i.e., the material which is to be printed on the print surface) is placed on the opposite surface of the screen. The is prevented by the negative pattern from passing through the screen in the negative areas, and the printing ink is sufficiently thixotropic that it does not pass through the portions of the screen in the positive pattern until pressure is applied over the printing ink, e.g., by running a squeegee over the printing ink so as to push the printing ink through the positive areas. Therefore, during such pressing, the blocking material in the negative areas blocks the passage of the printing ink through the screen, while printing ink passes through the positive areas. As a result, the printing ink is deposited on the print surface in a pattern resembling the positive pattern of the screen.

Screenprinting processes are relatively time consuming due to the need to, among other things, position the screen, apply the printing ink and press the printing ink through the regions of the positive pattern. In addition, the screens of a screenprinter in general frequently need to be replaced, further decreasing productivity and efficiency, e.g., due to the screen being torn when a semiconductor substrate breaks or chips (which would also necessitate removal of broken pieces to avoid repeated screen tearing), or otherwise presents a sharp edge, etc.

In addition, such screenprinting techniques in general require that the printing ink have specific properties, e.g., that they are sufficiently thixotropic. As a result, the range of compositions which can be used as conductive printing inks is limited. Also, screenprinting techniques generally require that the printing ink have a viscosity within a fairly specific range. Similarly, screenprinting techniques are unfavorably affected by variance in printing ink viscosity and/or variance in printing ink formulation. Such variances can be troublesome to control adequately. In addition, as a result of such limitations on the types of conductive printing inks which can be used in a screenprinting technique, it is typically deemed necessary to employ conductive printing inks which happen to emit significant amounts of volatile organic compounds, particularly during high-temperature drying steps, raising safety and environmental issues.

Also, with screenprinting techniques, it is generally not possible to finely control the thickness of the applied printing ink from one semiconductor substrate to another. In addition, in order to vary the thickness of the applied printing ink, it is generally necessary to change the screen (i.e., to use a different screen).

In addition, using a screenprinting technique, it is generally not possible to print a pattern which extends all the way to the extreme edges of a surface of a semiconductor substrate. That is, in general, when using a screenprinting technique, a border is formed around the extreme edges of the surface of the semiconductor substrate, in which border no printing ink is deposited.

Furthermore, in a screenprinting technique, a surface area printed in a single screenprinting operation cannot exceed the surface area of the screen. Also, there are limits on the overall size of the screen.

Also, screenprinting cannot in general be carried out as a continuous operation, and generally calls for stopping and abruptly moving the items being printed, as well as flipping and otherwise handling the items being printed, especially if being printed on opposite surfaces. In addition, screenprinting is relatively intolerant of long-term continuous operation and/or idle-run, i.e., the printing ink tends to dry on the screens during breaks or overnight.

In addition, in general, screenprinting techniques have a relatively low tolerance to defects in the article being printed, e.g., chips, missing corners, bow and taper of the semiconductor substrate, etc., or breakage of the article being printed (e.g., resulting in damage, significant down-time or maintenance, etc.). Also, screenprinting techniques have a low tolerance to printing ink which contains solid chips or particles, e.g., from broken wafers.

Additional considerations include the floor space required for screenprinting, the number of screen printers required to produce a given contact pattern, the frequency of breakage of the semiconductor substrates, solder strength of the product and resistance to the contact peeling from the semiconductor substrate on which it is applied.

It would be of great importance to provide a method and apparatus for applying one or more electrical contact to a semiconductor substrate while eliminating or reducing one or more of the drawbacks and/or limitations of conventional screenprinting, without significantly detracting from any of the mechanical, chemical and electrical properties of the contact or contacts. It would be particularly important to provide such a method and apparatus that could apply electrical contacts which include two or more materials in any desired respective patterns.

In particular, it would be of great importance to provide an apparatus (and a method) which can apply electrical contacts to a semiconductor substrate more rapidly (i.e., which can achieve higher throughput) than by screenprinting, which does not require frequent replacement of any of the components of the apparatus, which can be carried out with a wider variety of conductive inks (e.g., which can result in lower emission of volatile organic compounds or no emission of volatile organic compounds) than conductive printing inks used in screenprinting without unduly increasing cost, which is more tolerant of conductive ink viscosity variation and/or conductive ink formulation variation, which can readily and efficiently be controlled to provide differing thicknesses of the applied conductive ink and/or which can provide fine-control of the thickness of the applied conductive ink, which can readily apply conductive ink all the way to the edges of a semiconductor substrate, which can be applied to surfaces having a variety of surface areas, which can be applied efficiently to large surface areas, which has a high tolerance to defects in the semiconductor substrates, which can save floor space, and/or which can reduce the frequency of breakage of semiconductor substrates.

Solar-electric technology has evolved as a complex and intricate combination of structural, chemical and electrical characteristics which must be satisfied. In general, it is not possible to vary a method of manufacture or a material used in making a PV cell in order to improve or simplify one aspect, without causing significant and often deleterious effects on one or more other aspects of the . PV cell or its performance. Accordingly, while it is easy to suggest a modification to a method and/or apparatus for producing a solar device or a component thereof, it is quite another thing to successfully implement such a modification while balancing the other requirements and favorable attributes of the process or apparatus.

Suggestions have been made in the past with regard to different possible types of methods and apparatuses for printing contacts, without providing detailed information regarding how such printing could be carried out while avoiding disruption of one or more of the critical structural, chemical and electrical demands which must be met by the contacts in order to provide a viable PV cell.

In accordance with the present invention, as described below, a method and apparatus are provided which successfully implement a relatively drastic modification to a conventional process without upsetting the balance among the necessary and/or desirable electrical, mechanical and chemical characteristics of the solar device.

### BRIEF SUMMARY OF THE INVENTION

According to the present invention, there is provided an apparatus (and a method) for applying one or more contacts to a semiconductor substrate, which can apply the contacts to a semiconductor substrate more rapidly than by screenprinting, which does not require frequent replacement of any of the components of the apparatus, which can be carried out with a wider variety of conductive inks than with screenprinting without unduly increasing cost, which is more tolerant of conductive ink viscosity variation and/or conductive ink formulation variation, which can readily and efficiently be controlled to provide differing thicknesses of the applied conductive ink and/or which can provide fine control of the thickness of the applied conductive ink, which can readily apply conductive ink all the way to the edges of a semiconductor substrate, which can be applied to surfaces having a variety of surface areas, which can be applied to large surface areas efficiently, which has a high tolerance to defects in the semiconductor substrates, which can save floor space, and/or which can reduce the frequency of breakage of semiconductor substrates.

In accordance with a first aspect of the present invention, there is provided an apparatus for applying at least one electrical contact to a semiconductor substrate, the apparatus comprising at least first and second applicator rolls rotatable about respective axes, and at least a first conveyor. The first rotatable applicator roll comprises a first roll printing surface which has at least one raised first pattern surface. Each raised first pattern surface is positioned such that upon rotation of the first rotatable applicator roll, each raised first pattern surface passes through a first printing space. As a result, a first semiconductor substrate surface of a semiconductor substrate passing through the first printing space while the first roll printing surface is covered with a first conductive ink and the first rotatable applicator roll is being rotated will come into contact with the first conductive ink on at least part of the raised first pattern surface, and will not come into contact with first conductive ink on substantially all of the first roll printing surface other than the raised first pattern surface. Accordingly, a first conductive ink pattern will be deposited on the first semiconductor substrate surface.

The first conveyor is operable to convey a semiconductor substrate to the second rotatable applicator roll after the semiconductor substrate passes through the first printing space.

The second rotatable applicator roll comprises a second roll printing surface which has at least one raised second pattern surface. Each raised second pattern surface is positioned such that upon rotation of the second rotatable applicator roll, each raised second pattern surface passes through a second printing space. As a result, the first semiconductor substrate surface of the semiconductor substrate passing through the second printing space while the second roll printing surface is covered with a second conductive ink and second rotatable applicator roll is being rotated about the second axis will come into contact with the second conductive ink on at least part of the raised second pattern surface, and will not come into contact with second conductive ink on substantially all of the second roll printing surface other than the raised second pattern surface. Accordingly, a second conductive ink pattern will be deposited on the first semiconductor substrate surface.

Preferably, adjacent regions of the first conductive ink pattern and of the second conductive ink pattern include a slight area of overlap in order to ensure conductivity between the respective conductive ink patterns. Preferably, the first conductive ink pattern and the second conductive ink pattern together cover substantially an entirety of the first semiconductor substrate surface, optionally except for a border region around an edge of the first semiconductor substrate.

There may further be provided a first dryer between the first rotatable applicator roll and the second rotatable applicator roll. Where such a dryer is provided, the first conveyor is preferably operable to convey semiconductor substrates continuously through a first drying region in which the first dryer is positioned and then to the second rotatable applicator roll (alternatively, the first conveyor may convey the semiconductor substrates to the first dryer, and then the first conveyor or a different conveyor may convey the semiconductor substrates to the second rotatable applicator roll).

Optionally, there is further provided a second dryer positioned in a second drying region, and a second conveyor. In such instances, the second conveyor is preferably operable to convey a semiconductor substrate to the second drying region after the semiconductor substrate passes through the second printing space.

Optionally, there is further provided a device which is operable to provide a second contact on the semiconductor substrate, preferably such device being a second surface printer which is operable to provide a second contact on a second semiconductor substrate surface of the semiconductor substrate.

Optionally, there is further provided a firing furnace, and one or more conveyor which is operable to move the semiconductor substrate into the firing furnace after one or more contacts have been printed thereon, and out of the firing furnace after the semiconductor substrate has been fired.

In a preferred aspect, the present invention employs one or more hot melt conductive inks, i.e., an ink which is solid at room temperature, which ink is deposited on a semiconductor substrate at an elevated temperature at which the ink is liquid, and which ink solidifies when cooled to form a solid conductive contact region.

Alternatively, the present invention can employ any other suitable conductive inks, e.g., a standard conductive inks, i.e., an ink which is liquid at room temperature (e.g., about 22° C.) and which is deposited on a semiconductor substrate at, e.g., room temperature, such ink comprising a solvent which, upon subjecting the ink deposited on a semiconductor substrate to heating, evaporates in order to dry the ink and leave a solid conductive contact region.

In a second aspect of the present invention, there is provided an apparatus for applying at least one electrical contact to a semiconductor substrate, comprising at least a first tank which contains a first conductive hot melt ink, and at least a first rotatable applicator roll as described above.

The present invention is further directed to a method for applying at least one electrical contact to a semiconductor substrate, comprising passing a semiconductor substrate through a first printing space as described above, rotating a first applicator roll as described above to deposit a first conductive ink pattern on the first semiconductor substrate surface, conveying the semiconductor substrate from the first printing space to a second printing space, passing the semiconductor substrate through a second printing space as described above, and rotating a second applicator roll as described above to deposit a second conductive ink pattern on the first semiconductor substrate surface.

The method may further comprise drying the semiconductor substrate after passing it through the first printing space and before passing it through the second printing space.

The method may further comprise drying the semiconductor substrate after passing it through the second printing space.

Optionally, the method further comprises providing a second contact on the semiconductor substrate, preferably a surface contact on a second semiconductor substrate surface of the semiconductor substrate.

Optionally, the method further comprises firing the semiconductor substrate after one or more contact regions have been applied. In a further aspect of the present invention, there is provided a method for applying at least one electrical contact to a semiconductor substrate, comprising passing a semiconductor substrate through a first printing space, and rotating about a first axis a first applicator roll as described above, wherein each raised first pattern surface passes through a first ink space containing a first conductive hot melt ink and through a first printing space, whereby a first conductive ink pattern of hot melt ink is deposited on the first semiconductor substrate surface.

The invention may be more fully understood with reference to the accompanying drawings and the following description of the embodiments shown in those drawings. The invention is not limited to the exemplary embodiments and should be recognized as contemplating all modifications within the skill of an ordinary artisan.

### BRIEF DESCRIPTION OF THE DRAWING FIGURES

FIG. 1 is a schematic view of an embodiment of a rotatable applicator roll according to the present invention, along with associated equipment.

FIG. 2 is a front view of an applicator roll having a raised pattern on its surface according to the present invention.

FIG. 3 is an overhead schematic view of a preferred embodiment of a conveyor according to the present invention.

FIG. 4 is a front view along line IV-IV of FIG. 3.

FIG. 5 is a front view of another applicator roll having a raised pattern on its surface according to the present invention.

FIG. 6 is a top view of a surface of a semiconductor substrate on which a first conductive ink and a second conductive ink have been applied in accordance with the present invention.

FIG. 7 is a top view of a surface of another semiconductor substrate on which a first conductive ink and a second conductive ink have been applied in accordance with the present invention.

FIG. 8 is an overhead view of a scraper blade in accordance with the present invention.

FIG. 9 is a schematic view of a modified embodiment of a system according to the present invention.

### DETAILED DESCRIPTION OF THE INVENTION

As a result of the present invention achieving a method by which a conductive ink can be applied in a specific pattern on a semiconductor substrate surface to produce a specific dried ink pattern on the semiconductor substrate surface in place of a conventional screenprinting step (e.g., first and second different conductive ink compositions can be applied in different patterns on a semiconductor substrate surface to produce respective first and second dried ink patterns using respective first and second rotatable applicator rolls, in place of two or more conventional screenprinting steps), the method according to the present invention can be carried out continuously (thereby avoiding treating the semiconductor substrates more gently, by avoiding stopping and/or abruptly moving the semiconductor substrates) and can readily be automated, and therefore can be carried out more rapidly, providing higher throughput rates. Further, the method and apparatus of the present invention make it possible to operate endlessly, if desired, and to endure sustained idling (e.g., during breaks or overnight), if desired. Also, using the method and apparatus according to the present invention, it is possible to apply contacts to both surfaces of a semiconductor substrate with minimum handling (e.g., avoiding flipping the semiconductor substrate). In addition, as discussed below, using the method and apparatus according to the present invention, a wider variety of conductive ink compositions can be employed, including ink compositions which have lower viscosity, ink compositions which have higher viscosity, ink compositions which have less homogeneity and/or ink compositions which result in lower emission (or no emission) of volatile organic compounds. As discussed below, by virtue of the greater flexibility in the choice of conductive inks, it is possible to reduce or eliminate problems or drawbacks which would otherwise have been caused by replacing the screenprinting technique of the prior art processes with the ink application method and apparatus according to the present invention.

In addition, as described below, in accordance with the method and apparatus according to the present invention, it is possible to finely control the thickness of the applied ink composition irrespective of the thickness of the semiconductor substrate, and to very efficiently change the thickness of the ink composition being applied to the semiconductor substrates.

In addition, by virtue of the ability according to the present invention to apply ink compositions using rotatable applicator rolls, it is possible to print all the way to the edges of the semiconductor substrate surface being printed. In addition, semiconductor substrates of virtually any length can be accommodated by the method and apparatus of the present invention, because such semiconductor substrates can simply continue to be moved through the printing spaces through which the raised pattern surfaces of the respective applicator rolls endlessly pass by way of continuous rotation. Also, semiconductor substrates of virtually any width can be accommodated by using an applicator roll have a width as wide as is needed.

In addition, because the rotatable applicator rolls according to the present invention (unlike screens used in screenprinting) do not have to be made of relatively delicate material, they are less susceptible to damage resulting from broken semiconductor substrates, or defects in the semiconductor substrates, e.g., which produce sharp edges or regions, thereby avoiding damage and significant down-time and/or maintenance requirements. Also, the method and apparatus of the present invention can operate with conductive ink which contains chips, particles, etc., e.g., from broken semiconductor substrates. Similarly, because of the flexibility in selection of materials out of which the rotatable applicator rolls can be made, e.g., durable materials and/or pliant materials, the method and apparatus according to the present invention is more tolerant of defects in the semiconductor substrates (e.g., chips, missing corners, nonplanarity of the semiconductor substrate, etc.) than in a screenprinting technique. For the same reasons, use of the method and/or apparatus of the present invention generally results in a lower frequency of breakage of the semiconductor substrates.

In addition, the present invention addresses a number of problems which would otherwise be introduced as a result of printing on rotatable applicator rolls rather than using a screenprinting technique. For example, one such problem is the tendency for ink to be applied to the side edges of the semiconductor substrate and/or the opposite surface of the semiconductor substrate. As discussed below, preferably, when necessary, such problems are reduced or eliminated by withdrawing the semiconductor substrate away from the printing space at a speed which exceeds the speed at which the semiconductor substrate moves through the printing space (i.e., while being printed). Alternatively or additionally, if necessary, “wraparound” (i.e., printing on a trailing edge and/or on the opposite surface of the semiconductor substrate, adjacent to the trailing edge) can be reduced or eliminated by using a conductive ink having a relatively low viscosity, because the method and apparatus according to the present invention enable use of conductive inks having such lower viscosity.

The present invention can be used in connection with any kind of semiconductor substrate (i.e., wafer). For example, the semiconductor substrate can be made of any semiconductor, e.g., silicon, germanium, gallium arsenide, etc., and can be polycrystalline or in the form of a single crystal. The semiconductor substrate is typically one which has been doped with an n-type dopant and a p-type dopant to provide one or more p-n junctions, but the present invention is equally applicable to a semiconductor substrate which has not been doped or which has only been partially doped.

Polycrystalline semiconductor substrates preferably have a thickness in the range of from about 700 μm to about 1000 μm. Single crystal silicon semiconductor substrates preferably have a thickness in the range of from about 500 μm to about 800 μm. As discussed below, however, the method and apparatus of the present invention can be used to print on semiconductor substrates of any desired thickness.

In addition, the present process and apparatus are effective for printing contact regions on semiconductor substrates having any desired degree of flexibility, e.g., extremely rigid semiconductor substrates or extremely flexible semiconductor substrates.

Each of the rotatable applicator rolls has a roll printing surface which has at least one raised pattern surface. Each rotatable applicator roll can be generally any shape which, when rotated about its axis, has the substantial entirety of each of the raised pattern surfaces pass through a printing space. For example, the first rotatable applicator roll is preferably substantially cylindrical, having a raised pattern surface (the raised pattern surface preferably lying within areas which lie on a space defined as an imaginary substantially cylindrical larger diameter coaxial space), but it could alternatively be substantially frustoconical (likewise having a raised pattern surface lying within areas which lie on a substantially frustoconical larger coaxial space).

Preferably, the length (i.e., in the case of a cylinder, from circular end to circular end) of the rotatable applicator rolls is about the same as the width of the semiconductor substrates on which the applicator rolls are to print. Preferably, in the case of a cylindrical applicator roll, the circumference of the applicator roll is approximately equal to the length of the semiconductor substrates on which the applicator roll is to print. In the case where a printing surface of a single crystal silicon semiconductor substrate is being printed with an aluminum pattern, for example, in order to maximize the voltage of the current produced by the resulting PV cell, it is preferable to print aluminum all the way to the edges of the printing surface. If desired, however (e.g., for a polycrystalline silicon semiconductor substrate), notches can be formed on one or both end of the applicator rolls in order to provide a non-printed border on the sides of the semiconductor substrates. Similarly, if desired, a notch (or notches) can be formed across the length of the applicator roll to assist in avoiding printing on the leading and/or trailing edges of the semiconductor substrates.

Each rotatable applicator roll can be made of any suitable material. For example, suitable materials include rubber, plastic, metal, etc. A preferred material for the rotatable applicator roll is stainless steel. Another example of a possible configuration would be an applicator roll which comprises a material other than rubber and including an outer layer formed of rubber, e.g., silicon rubber. Each rotatable applicator roll (or at least the outer portion of each rotatable applicator roll) can, if desired, be compliant, thereby facilitating printing on semiconductor substrates which may have some surface irregularities, and also contributing to the ability to accommodate stiff semiconductor substrates.

In some instances, it is preferred for one or more of the rotatable applicator rolls to have a textured surface. By providing a rotatable applicator roll having a textured surface, it is possible to employ lower viscosity conductive ink, and in general to achieve more uniform coating.

The first conductive ink contains at least one conductive material which is to be applied to the semiconductor substrate, as well as at least one solvent or other dispersing medium which is effective to dissolve, disperse, or otherwise liquify the conductive material. The first conductive ink preferably further includes one or more binder. As mentioned above, the present invention makes it possible to employ any of a wide variety of conductive ink compositions. In particular, the present invention, in contrast to conventional screenprinting techniques, can employ conductive ink compositions having a wide range of viscosity, e.g., from as low as about 10 poise to as high as about 2000 poise, such as from about 100 poise to about 800 poise. When using a conductive ink composition having a low viscosity, e.g., below 100 poise, such as 10 poise, it is especially preferred for the applicator roll to be textured.

Preferably, as the first conductive ink, a hot melt ink is employed. A hot melt ink is an ink which is solid at room temperature. Such hot melt ink is deposited on a semiconductor substrate at an elevated temperature at which the ink is liquid, and the ink can be solidified by cooling, so as to form a solid conductive contact region. According to the present invention, after applying a hot melt ink, no active cooling needs to be carried out, as a hot melt ink will typically set up in less than one second after application, after being applied and subjected to ambient temperature,conditions. If desired, however, active cooling could be carried out, e.g., by blowing cool gas on the deposited hot melt ink, or any other treatment which accelerates cooling. The solvents in such hot melt inks are typically solvents which, upon such cooling, result in no volatile organic compound emission (even heating such a hot melt ink to remove its solvent results in little or no volatile organic compound emission).

Alternatively, if desired, after being deposited on a semiconductor, the hot melt ink can be heated at a temperature at which the solvent is removed in order to solidify the hot melt ink. Any suitable treatment for heating the hot melt ink can be employed, several of which are discussed below in connection with drying standard inks. As mentioned above, the solvents in such hot melt inks are typically solvents which, upon heating to remove the solvent, result in little or no volatile organic compound emission.

Typical hot melt inks employ a solvent such as hexadecanol (cetyl alcohol) which, if heated, breaks down into relatively benign compounds, e.g., carbon dioxide and water. Where a hot melt ink is employed, except for ink that has been deposited on a semiconductor substrate, it is necessary for the hot melt ink to remain sufficiently hot that it remains liquid. There is a discussion below of use of a heated tank which is effective to maintain the hot melt ink in its liquid state (i.e., in which the hot melt ink is heated in the tank and heats the rolls with which the hot melt ink comes into contact, so that the hot melt ink in the tank and on the rolls remains liquid through heating of only the tank, but it dries quickly and is quickly solidified after being deposited on a semiconductor substrate).

Hexadecanol is a long chain alcohol that is solid at room temperature. The melting point can be varied (by the addition of other materials which affect melting point, such materials being well known) between about 50° C. and about 80° C., and the boiling point is about 344° C.

Hot melt inks also reduce the tendency (apparently as a result of local solidification) for ink to wrap around the leading and trailing edges of the semiconductor wafers. A fritted hot melt ink can be employed in order to reduce or eliminate oxide formation (e.g., aluminum oxide) on the printed patterns during firing.

If an attempt were made to employ a hot melt ink in a process which includes a conventional screenprinting technique (as opposed to the method and apparatus of the present invention), it would be necessary to provide a heated squeegee, as well as a heated screen, which would significantly increase cost relative to standard conventional printing screens, i.e., the cost would be about four times as expensive).

Alternatively, any other suitable conductive ink can be employed as the first conductive ink, e.g., a standard ink comprising silver, together with small amounts of aluminum, one or more solvent and one or more binder. A specific representative example of such a conductive ink comprises about 20 weight % to about 35 weight % of a solvent (e.g., terpineol, texanol or butyl carbitol), about 2 weight % of a binder (e.g., ethyl cellulose), from about 2 weight % to about 4 weight % aluminum, and the remainder silver. This conductive ink can further comprise silica, in an amount of from about 1 weight % to about 10 weight % silica.

One or more scraper blades may be employed, as necessary or desired, to remove conductive ink from one or more regions of roll surfaces where it is not desired (e.g., as described in connection with a preferred embodiment discussed below). Additionally or alternatively, one or more doctor blades may be employed, as necessary or desired, to meter the amount of conductive ink present on one or more regions of roll surfaces. Additionally or alternatively, one or more Meyer rods (i.e., wire wound rods) may be employed, as necessary or desired, to control the thickness of conductive ink deposited on a semiconductor substrate, i.e., to remove any excess conductive ink which may be printed on the semiconductor substrate.

In general, a variety of structures can be used to assist in guiding and conveying the semiconductor substrates through the apparatus according to the present invention.

The first conveyor can convey the semiconductor substrate directly, or substantially directly, from the first printing space to the second printing space. Preferably, the first conductive ink is dry (i.e., solidified) by the time the semiconductor substrate reaches the second printing space, in order to minimize or eliminate mixing of the first and second conductive inks.

Where the first conductive ink is a hot melt ink, which dries substantially immediately upon being cooled, no additional structure is required in order to solidify the first conductive ink. A hot melt ink cools and sets up substantially immediately upon being applied to a semiconductor substrate and subjected to ambient conditions. In such a case, the residence time between the first printing space and the second printing space can be short, e.g., less than about one second, meaning that the distance between the first printing space and the second printing space, which is preferably minimized, can be relatively short, depending on the speed that the first conveyor moves the semiconductor substrates.

Where the first conductive ink is a standard ink, it is preferred that the first conductive ink be subjected to a heat treatment after being applied to the semiconductor substrate and before the second conductive ink is applied to the semiconductor substrate. Such a heat treatment can be any suitable method of increasing the temperature of the ink. For instance, hot gas can be blown into contact with the ink, the ink can be heated by one or more infrared bulb and/or by one or more halogen lamp, the semiconductor substrate can be passed through a high-temperature drying space, etc. The heat treatment can thus be any method which is effective to heat the standard ink to a temperature at which its solvent is vaporized, and the duration of the heat treatment is preferably sufficient to vaporize all or substantially all of the solvent so as to achieve substantially complete drying of the first conductive ink before the semiconductor substrate reaches and passes through the second printing space. In the case of a standard silver-containing ink composition as described above, the temperature at which such solvent vaporizes is typically around at least 240° C. (under atmospheric pressure). Where such silver-containing ink is applied to a relatively small portion of the semiconductor substrate, such a heat treatment can be accomplished, e.g., by blowing hot gas at a temperature which is higher than the flash point (at the prevailing pressure condition) of the solvent, e.g., in the range of from about 350° C. to about 500° C., for a period of time of from about 2 seconds to about 10 seconds. Where a standard aluminum ink composition as described above is applied to a relatively large portion of the semiconductor substrate, such a heat treatment can be accomplished, e.g., by blowing hot gas at a temperature in the range of from about 350° C. to about 500° C. for a period of time of from about 20 seconds to about 60 seconds.

In such an instance (i.e., where the first conductive ink is a standard ink), the first conveyor preferably conveys the semiconductor substrate (which has passed through the first printing space) to a first drying region where the semiconductor substrate is subjected to a heat treatment. Preferably, the first conveyor moves the semiconductor substrate continuously through the first drying region and to the second printing space at such a rate (taking into account the length of the first drying region) that by the time the semiconductor substrate reaches the second printing space, the first conductive ink is substantially dry. Such movement can be at varying speeds. Alternatively, the semiconductor substrate can be conveyed by a plurality of conveyors, and movement is not necessarily continuous (e.g., one conveyor can convey the semiconductor substrate to a first drying region where the semiconductor substrate resides motionless for a period of time, and then another conveyor can convey the semiconductor substrate to the second printing space).

If desired, where a hot melt ink is employed as the first conductive ink, the hot melt ink could be subjected to a heat treatment as described above prior to passing the semiconductor substrate through the second printing space, e.g., in order to volatilize the solvent in the first conductive ink instead of allowing it to solidify or causing it to solidify. However, in general, if hot melt ink is employed and there is a desire to remove its solvent (e.g., as discussed below, if the semiconductor substrate is going to be subjected to a high temperature in a later treatment, e.g., a firing treatment, particularly if it is in contact with a structure, e.g., a belt, during such high temperature treatment), such solvent is more conveniently removed after all the hot melt inks have been applied, e.g., after the second hot melt ink has been applied, so that such a solvent vaporization method removes the solvent from all such deposits of hot melt inks.

In a preferred aspect of the present invention, the first conveyor moves the semiconductor substrate away from the first printing space at a speed which is greater than the speed that the semiconductor substrate passes through the first printing space, i.e., the semiconductor substrate accelerates as it exits the first printing space. Preferably, the speed of the semiconductor substrate is about 50% higher after it exits the first printing space than its speed as it passes through the first printing space. As a result of such acceleration, there is a reduced tendency for conductive ink to be applied to the trailing edge of the semiconductor substrate.

As mentioned above, the second rotatable applicator roll comprises a second roll printing surface which has at least one raised second pattern surface. Each raised second pattern surface is positioned such that upon rotation of the second rotatable applicator roll, each raised second pattern surface passes through the second printing space.

The description above concerning the first rotatable applicator roll is applicable to the second rotatable applicator roll (although the structure and/or composition of the second rotatable applicator roll can differ, if desired, from that of the first rotatable applicator roll). The second conductive ink contains at least one conductive material which is to be applied to the semiconductor substrate, as well as at least one solvent or other dispersing medium which is effective to dissolve, disperse, or otherwise liquify the conductive material. The description above concerning the first conductive ink is applicable to the second conductive ink as well. That is, the present invention makes it possible to employ any of a wide variety of conductive ink compositions as the second conductive ink, and preferably, the second conductive ink is a hot melt ink, although other ink compositions, e.g., standard inks, can instead be employed.

As described above, one or more scraper blades may be employed, as necessary or desired, to remove conductive ink from one or more regions of roll surfaces where it is not desired, one or more doctor blades may be employed, as necessary or desired, to meter the amount of conductive ink present on one or more regions of roll surfaces, and/or one or more Meyer rods may be employed, as necessary or desired, to control the thickness of conductive ink deposited on a semiconductor substrate.

In a preferred aspect, there may further be provided a second conveyor which conveys the semiconductor substrate from just downstream of the second printing space to one or more downstream treatment device, e.g., to a second conductive ink drying region or to a second surface contact printer. Alternatively, after the semiconductor substrate passes through the second printing space, it can be manually conveyed to a downstream treatment device such as a second conductive ink drying region or a second surface printer (e.g., the semiconductor substrate can be ejected from the second printing space into a tray, picked up by an operator with a vacuum wand and placed onto a furnace belt with the printed surface facing up, and the furnace belt carrying the semiconductor substrate into a drying furnace).

If desired, the second conveyor can move the semiconductor substrate away from the second printing space at a speed which is greater (preferably by about 50%) than the speed that the semiconductor substrate passes through the second printing space (similar to the preferred aspect described above with respect to the first conveyor). Similar to the discussion above in connection with the first conveyor, as a result of such acceleration, there is a reduced tendency for second conductive ink to be applied to the trailing edge of the semiconductor substrate.

As with the first conductive ink, where the second conductive ink is a hot melt ink, which dries substantially immediately upon being cooled, no additional structure is required in order to solidify the first conductive ink. In such a case, the residence time between the second printing space and any next downstream treatment device can be short, e.g., less than about one second. Therefore, the distance between the second printing space and any next downstream treatment device, which distance is preferably minimized, can be relatively short, depending on the speed that the second conveyor, if included, moves the semiconductor substrates.

Where the second conductive ink is a standard ink, it is preferred that the second conductive ink be subjected to a heat treatment after being applied to the semiconductor substrate and before the semiconductor substrate is subjected to the next downstream treatment (if any, e.g., application of a second surface contact). As with the standard ink heat treatment discussed above, such a heat treatment can be any suitable method of increasing the temperature of the ink for a time period sufficient to vaporize all or substantially all of the solvent so as to achieve substantially complete drying of the second conductive ink before the semiconductor substrate reaches the next downstream treatment. The heat treatment can thus be any method which is effective to heat the standard ink to a temperature at which its solvent is vaporized, and the duration of the heat treatment is preferably sufficient to vaporize all or substantially all of the solvent so as to achieve substantially complete drying of the second conductive ink. Accordingly, the discussion above regarding heat treatments of standard inks is applicable. For example, In the case where the heat treatment of the second conductive ink is accomplished by blowing hot gas, it would be possible to employ a device which is similar to the device used for blowing hot gas toward the first conductive ink, except that the hot gas would preferably be blown toward the second conductive ink, and the residence time might be different (e.g., the length of the dryer might be different and/or the speed of conveyance might be different).

Where the second conductive ink is a standard ink, the second conveyor preferably conveys the semiconductor substrate (which has passed through the second printing space) continuously through a second conductive ink drying region, preferably at such a rate (taking into account the length of the drying region) that by the time the semiconductor substrate reaches the end of the second conductive ink drying region, the second conductive ink is substantially dry. Such movement can be at a substantially constant speed or, if desired, at varying speeds. The second conveyor, or another conveyor, can convey the semiconductor substrate from the second conductive ink drying region to a next downstream device, if any, e.g., a second surface printer. Alternatively, the semiconductor substrate can be conveyed by a plurality of conveyors, and movement is not necessarily continuous (e.g., one conveyor can convey the semiconductor substrate from just downstream of the second printing space to a second conductive ink drying region where the semiconductor substrate resides motionless for a period of time, and then another conveyor can convey the semiconductor substrate away, e.g., to a next downstream device, e.g., a second surface printer).

If desired, where a hot melt ink is employed as the second conductive ink, the second conductive ink could be subjected to a heat treatment as described above, e.g., in order to vaporize the solvent in the second conductive ink instead of allowing it to solidify or causing it to solidify.

In general, the two or more conductive ink patterns can be printed on the one side of a semiconductor substrate in any desired order.

Before or after printing the contact (i.e., the two or more conductive ink patterns) on the first semiconductor substrate surface, a contact is preferably applied to the “opposite” surface of the semiconductor substrate (i.e., the surface of the semiconductor substrate which is opposite the surface on which the first and second conductive inks have been printed and dried) using a second surface printer. The second surface printer is any device which is effective to provide a suitable contact region on the opposite surface of the semiconductor substrate. The second surface printer can be similar to the structure described above for printing the first and second conductive inks, including as many rotatable applicator rolls as are necessary to deposit the desired pattern or patterns on the opposite surface of the semiconductor substrate. Alternatively, the second surface printer can be a conventional screenprinter (preferably an in-line screenprinter) or a fine-line dispenser (examples of which are well known, e.g., a synchronous positive displacement pumping system for producing precision deposited images of any fluid material sold by Ohmcraft, Inc. under the name Micropen, Model 400), or any other structure which is effective to provide the desired pattern or patterns.

After the desired pattern or patterns have been printed on one or both surfaces of the semiconductor substrate, if firing is required or desired, the semiconductor substrate can be conveyed, e.g., by a additional conveyor, or manually, to a firing furnace.

The firing furnace, if employed, can be any structure capable of providing the temperature and other conditions desired for firing the printed surfaces of the semiconductor substrate. A wide variety of such devices are well known. In instances where one or more hot melt ink is employed as a conductive ink and is not subjected to a heat treatment in order to vaporize its solvent, the solvent in the hot melt ink will vaporize during firing. Depending on the method of firing, it may be that such solvent causes some of the deposited conductive ink to become textured or otherwise distorted during firing, e.g., if the hot melt ink is in contact with a belt which conveys the semiconductor substrates through the firing furnace. If such texturization or other distortion occurs and there is a desire to eliminate it, such can be accomplished either by changing the firing process (e.g., by employing some process in which the hot melt ink is not in contact with another structure over a large surface area) or by vaporizing the hot melt solvent before firing (e.g., as discussed above, by subjecting the hot melt ink to an elevated temperature drying process immediately after depositing it on the semiconductor substrate).

A number of different structures can be used in order to assist in providing steady flow of conductive ink to each of the rotatable applicator rolls. For example, any of the rotatable applicator rolls can be positioned such that at least the raised pattern surface on the roll passes through a space containing a conductive ink (e.g., a conductive ink contained within a tank) and then through the printing space for that rotatable applicator roll.

Alternatively, in a preferred aspect of the invention, for each applicator roll, a rotatable tank roll can be provided, which is positioned so as to have a surface which (as the tank roll is rotated) passes through a space containing a conductive ink (e.g., a conductive ink contained within a tank) and then the conductive ink on the surface of the tank roll comes into contact with the raised pattern surface of the rotatable applicator roll so as to transfer conductive ink to the raised pattern surface, which then passes through the printing space for that applicator roll.

A tank roll can be generally any shape which, when rotated about its axis, has one or more outer surfaces which come into contact with the corresponding raised pattern surface or surfaces of the applicator roll, or passes through a location which is so close to the raised pattern surface or surfaces of the applicator roll that at least a portion of conductive ink on the outer surface or surfaces of the tank roll is transferred to the raised pattern surface or surfaces of the applicator roll. For example, an example of a preferred tank roll is generally cylindrical with raised outer surfaces which, upon rotation of the tank roll and its corresponding applicator roll, mirror the raised pattern surfaces of the applicator roll. However, the tank roll could be generally any shape which is effective to transfer conductive ink to the raised pattern surface or surfaces of the applicator roll.

Tank rolls can be made of any suitable material. For example, suitable materials include rubber, plastic, metal, etc. A particularly preferred tank roll comprises an aluminum roll.

In some instances, it is preferred for such a tank roll to have a textured surface. By providing a tank roll having a textured surface, it is possible to employ lower viscosity conductive ink, and in general to achieve more uniform coating.

Additionally, if desired, one or more intermediate rolls can be provided between such a tank roll and the applicator roll.

Each conductive ink is preferably provided in respective tanks. In cases where hot melt inks are being employed, such tanks must be sufficient to withstand the heat required to keep the conductive ink in a liquid state. Preferably, the tanks include heating elements which provide the heat needed to keep the conductive ink in a liquid state. Typically, heating the tank to a temperature greater than about 55° C. or 600° C. will be sufficient. The hot melt ink heated in the tank heats the rolls with which the hot melt ink comes into contact, so that the hot melt ink in the tank and on the rolls remains liquid through heating of only the tank, but the hot melt dries quickly and is quickly solidified after being deposited on a semiconductor substrate. Alternatively, if desired, additional heating elements can be provided to maintain hot melt ink in the liquid state until it is deposited on a semiconductor substrate.

In addition, one or more rotatable feed roll can be provided opposite the applicator rolls with respect to the printing space, i.e., the printing space is defined between the applicator roll and the feed roll. In such an apparatus, the feed roll assists in pushing the semiconductor substrates through the printing space between the applicator roll and the feed roll.

Such a feed roll can be generally any shape which, when rotated about its axis, has at least a portion of its outer surface assist in pushing semiconductor substrates therethrough. For example, a preferred example of such a feed roll is preferably substantially cylindrical with one or more raised, portions each having a groove in which an O-ring is positioned), but it could alternatively be substantially cylindrical or substantially frustoconical (likewise optionally having one or more raised portions).

Feed rolls can be made of any suitable material. For example, suitable materials include rubber, plastic, metal, etc. A particularly preferred feed roll comprises a cylindrical aluminum member having a pair of hubs, each hub having a groove in which a rubber O-ring is positioned. By providing such a feed roll, there is a reduced tendency for ink to be deposited on the trailing edge of the semiconductor substrate. Where a feed roll comprises a material other than rubber, the feed roll preferably includes one or more outer contact portions (i.e., portions which come into contact with the semiconductor substrate) formed of rubber, e.g., silicon rubber and/or an O-ring. Preferably, each feed roll is compliant (or at least the outer portion of the feed roll is compliant, or a compliant O-ring is provided), thereby facilitating feeding stiff semiconductor substrates. If desired, the feed roll may have one or more textured surfaces, e.g., to provide greater friction between the feed roll and the semiconductor substrates passing through the adjacent printing space.

Furthermore, it is possible to rotate one or more of the rotatable applicator rolls in a direction which is opposite to the direction of motion of the semiconductor substrate as the semiconductor substrate passes through the printing space adjacent to that rotatable applicator roll.

As another alternative, one or more members can be provided on which one or more conductive ink pattern is printed and later transferred to a semiconductor substrate. Such members, if employed, are preferably formed of rubber.

In addition, there may be employed any number of additional rotatable applicator rolls and associated equipment, as described herein, to apply any number of additional conductive inks in respective patterns. As mentioned above, preferably, adjacent regions of conductive ink are overlapped to at least a slight degree, e.g., from about 1 mm to about 200 mm, to ensure conductivity between the respective conductive ink patterns.

Similarly, there may be employed any number of additional conveyors, as described herein, for conveying semiconductor substrates from any printing space to any drying region and/or any printing space.

Preferably, automated feeders and/or takeouts are employed where necessary in order to automate part or all of the process. For example, belt conveyors, drive wheels, pick and place systems can be employed, as necessary, in order to rapidly transfer semiconductor substrates from one treatment to the next, and to avoid, where possible, human handling. Such automation can speed up production and also reduce mishandling and breakage of the semiconductor substrates.

The present invention can significantly reduce the space required to produce PV cells. For example, an apparatus according to the present invention for printing two conductive ink patterns on one side of a semiconductor substrate can replace two screenprinters and a drying furnace (a typical drying furnace is greater than thirty feet long) with a single six foot long apparatus (thereby not only reducing space requirements but also cost). In the case where first and second hot melt ink compositions are employed to print first and second conductive ink patterns on a semiconductor substrate and no high temperature drying step is employed, the apparatus according to the present invention for printing the two conductive ink patterns can be as short as two feet long, and potentially even shorter.

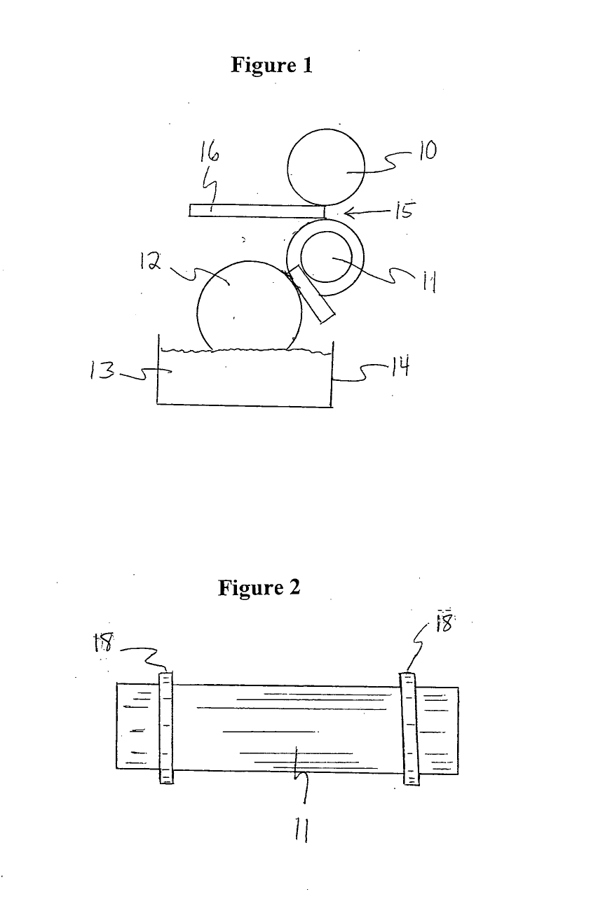

FIG. 1 depicts a first preferred embodiment of a rotatable applicator roll in accordance with the present invention.

In the embodiment shown in FIG. 1, a first printing space 15 is provided between a first feed roll 10 and a raised first pattern 18 of a first applicator roll 11. The raised first pattern 18 of the first applicator roll 11 is adjacent to a first tank roll 12 which is at least partially immersed in a first conductive ink 13 contained in a first tank 14. In this embodiment, the first feed roll 10 rotates in a counter-clockwise direction (i.e., as viewed from the side as shown in FIG. 1), while the first applicator roll 11 rotates in a clockwise direction (as viewed from the side as shown in FIG. 1). The first tank roll 12 rotates in a counter-clockwise direction (as viewed from the side as shown in FIG. 1), the outer surface of the first tank roll 12 picking up a layer of first conductive ink as the first tank roll 12 rotates through the first conductive ink 13 contained in the first tank 14. A portion of the first conductive ink on the surface of the first tank roll 12 is transferred to the first applicator roll 11 as the first tank roll 12 and the first applicator roll 11 rotate in opposite directions in close proximity to each other. A scraper blade 17 is provided adjacent to the tank roll 12 to scrape conductive ink from circumferential portions of the tank roll 12 which are not adjacent to the circumferential surface of the raised first pattern 18 of the applicator roll 11, and to remove conductive ink from side portions of the raised first pattern 18 (i.e., portions of the raised first pattern which are in the plane of the page on which FIG. 1 is printed). As a semiconductor substrate 16 is pushed through the first printing space 15 by the first feed roll 10 and the raised first pattern 18 of the first applicator roll 11, first conductive ink contained on the circumferential surface of the raised first pattern 18 of the first applicator roll 11 is transferred to the bottom surface of the semiconductor substrate 16.

In this embodiment, the speed of the applicator roll 11 is not limited, i.e., such speeds can be anywhere from 900 inches/minute or less up to 100 or 150 feet per minute; such rates can be increased with the use of pick-up machinery.

FIG. 2 is a front view of the first applicator roll 11 having a raised first pattern 18 on its surface.

By varying the thickness of the space between the first tank roll 12 and the raised first pattern 18 on the first applicator roll 11, the thickness of the first conductive ink applied to the semiconductor substrate 16 can be finely controlled. In accordance with a preferred aspect of the present invention, a knob, lever or other thickness adjustment structure is provided, the movement of which causes either or both of the first tank roll 12 and the first applicator roll 11 to move so as to change the thickness of the space between the first tank roll 12 and the raised first pattern 18 on the first applicator roll 11. Preferably, there are further provided markings or some other gauge which is indicative of the extent of movement of the thickness adjustment structure, and therefore is indicative of the thickness of the space between the first tank roll 12 and the raised first pattern 18 on the first applicator roll 11. Accordingly, the thickness adjustment structure can be calibrated by comparison of the thickness adjustment structure gauge setting and the resulting thickness of the applied conductive ink. Using such calibration, the thickness of conductive ink applied to semiconductor substrates can be precisely controlled and readily varied, as desired.

Preferably, where the first conductive ink comprises silver, it is applied at a thickness of from about 14 μm to about 26 μm, and when dried, is of a thickness of from about 12 μm to about 20 μm. However, as mentioned above, the thickness applied can be varied within a wide range, e.g., the thickness can be as small as from about 1.3 μm to about 1.5 μm, or as large as about 150 μm. In comparison, with a conventional screenprinting technique, it is typically not feasible to apply conductive ink in a thickness greater than about 25 μm.

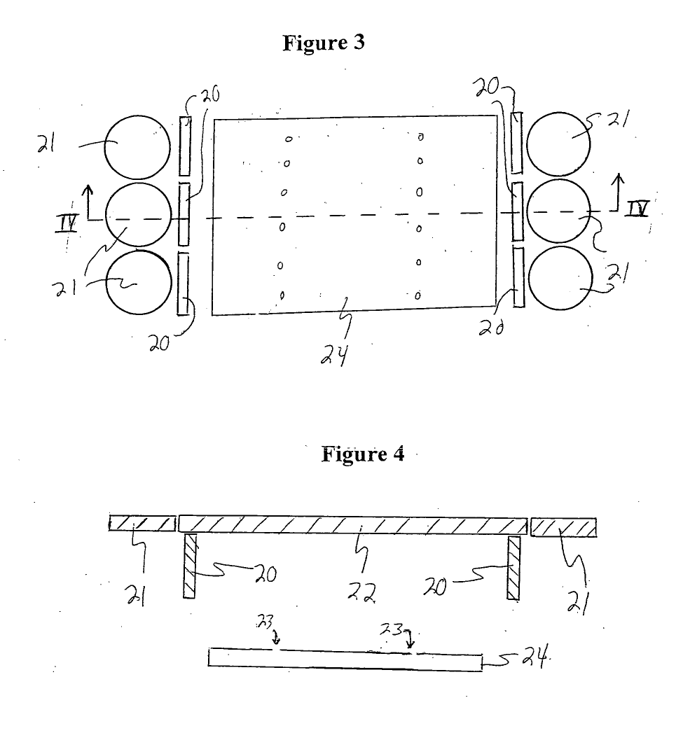

FIG. 3 is an overhead view of a preferred embodiment of a conveyor according to the present invention for use in providing a heat treatment (while conveying semiconductor substrates) after passing the semiconductor substrates through a printing space in which a standard ink is deposited on the semiconductor substrates, in order to vaporize the standard ink composition solvent (or, if desired, for providing a heat treatment to vaporize solvent of a hot melt ink). In this embodiment, after being printed on their bottom surface as they pass through the first printing space 15, each semiconductor substrate lands on the conveyor, which then transports the semiconductor substrate through the first drying region and then to a second printing space which is similar to the first printing space 15 (i.e., which includes a feed roll, an applicator roll, a tank roll, a tank, a scraper blade and conductive ink as schematically shown in FIG. 1, the raised pattern on the applicator roll making a pattern which differs from that of the raised first pattern 18, e.g., which overlaps such pattern only to a slight extent where the first and second printed patterns are adjacent). The conveyor includes a series of bottom rolls 20 and a series of side rolls 21.

FIG. 4 is a front view along line IV-IV of FIG. 3. FIG. 4 shows that the semiconductor substrate 22 rides along the tops of the bottom rolls 20 and adjacent to the side rolls 21 on its side edges. The bottom rolls 20 and the side rolls 21 are powered so as to rotate in the direction of movement of the semiconductor substrate, i.e., the side rolls 21 on the right side of FIG. 3 rotate in a counter-clockwise direction, the side rolls 21 on the left side of FIG. 3 rotate in a clockwise direction and the bottom rolls 20 rotate in the direction which pushes the semiconductor substrate 22 from the top of FIG. 3 toward the bottom of FIG. 3.

In this embodiment, the bottom rolls 20 and the side rolls 21 nearest to the first printing space 15 rotate at a speed such that the tangential velocity of the outer surfaces of the bottom rolls 20 and the side rolls 21 is about 50% higher than the tangential velocity of the outer surfaces of the feed roll 10 and the applicator roll 11, such that upon reaching the conveyor, the speed of movement of the semiconductor substrate increases by about 50% relative to its speed while passing through the first printing space. As discussed above, by doing so, there is a reduced tendency for first conductive ink to be applied to the trailing edge of the semiconductor substrate. The other bottom rolls 20 and side rolls 21 can rotate at similar speeds, whereby the semiconductor substrate continues to move through the drying region at a speed which is about 50% higher than the speed through which it passed through the first printing space, or the other bottom rolls 20 and side rolls 21 can rotate at a slower rate, whereby after exiting the first printing space at a speed of about 50% higher than the speed through which the semiconductor substrate passed through the first printing space, the speed of the semiconductor substrate decreases as it passes through the first drying region, thereby reducing the length of the drying region (and thus decreasing the overall size of the apparatus).

In the first embodiment, a plurality of openings (gas jets) 23 are provided in a plenum 24 are positioned within the first drying region at locations corresponding to where the first conductive ink has been applied, and air at a temperature of from about 350° C. to about 400° C. is fed through the openings 23 toward the first conductive ink, thereby rapidly drying the first conductive ink. In such an embodiment, a typical flow rate of air through the openings is from about 5 to about 20 cfm of compressed (e.g., 80 psi) house air.

In a modified embodiment of the drying region shown in FIGS. 3 and 4, which may or may not includes some or all of the rolls 20 and 21, there are provided fingers which push the semiconductor substrates forward and/or fingers which hold the semiconductor substrates from advancing too rapidly, and the semiconductor substrates may be suspended by the force of the gas being blown from the openings 23. If desired, the surface of the plenum 24 can be sloped in order to cause the semiconductor substrates to flow in the desired direction at the desired rate (or to assist in causing such motion). A further alternative is to employ a small belt furnace as the first drying region.

A conveyor for use in conveying semiconductor substrates after passing through a printing space in which a hot melt ink is deposited on the semiconductor substrates can be similar to the conveyor depicted in FIG. 3, except without the plenum 24 and the openings 23.

In this embodiment, a second printing space is provided between a raised second pattern of a second applicator roll and a second feed roll, similar to the first printing space 15 between the raised first pattern of the first applicator roll 11 and the first feed roll 10 shown in FIG. 1. The raised second pattern of the second applicator roll is adjacent to or in contact with a second tank roll which is at least partially immersed in a conductive ink contained in a second tank, similar to the raised first pattern of the first applicator roll 11 being adjacent to or in contact with the first tank roll 12 which is at least partially immersed in a conductive ink 13 contained in a first tank 14, as shown in FIG. 1. Similar to the structure shown in FIG. 1, in this embodiment, the second feed roll rotates in a counter-clockwise direction, the second applicator roll rotates in a clockwise direction and the second tank roll rotates in a counter-clockwise direction. The outer surface of the second tank roll picks up a layer of second conductive ink as the second tank roll rotates through the second conductive ink contained in the second tank. A portion of the second conductive ink on the surface of the second tank roll is transferred to the raised second pattern of the second applicator roll as the second tank roll and the raised pattern of the second applicator roll rotate in opposite directions in contact with each other. A scraper blade is provided adjacent to the second tank roll to scrape conductive ink from circumferential portions of the second tank roll which are not adjacent to the circumferential surface of the raised second pattern of the second applicator roll, and to remove conductive ink from side portions of the second raised pattern. As a semiconductor substrate is pushed through the second printing space by the second feed roll and the second applicator roll, second conductive ink contained on the raised second pattern of the second applicator roll is transferred to the bottom surface of the semiconductor substrate.

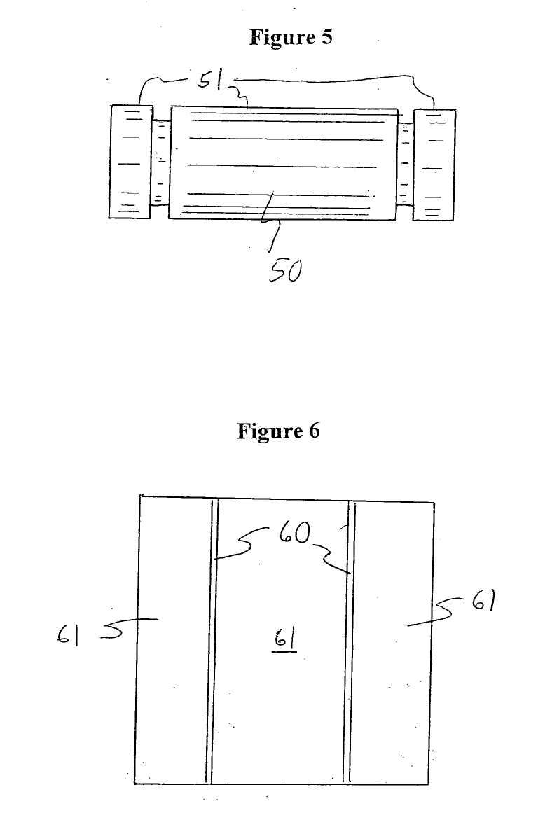

FIG. 5 is a front view of the second applicator roll 50 having the raised second pattern 51 on its surface.

The descriptions above regarding the first feed roll, the first tank roll, the first tank, are applicable to the second feed roll, the second tank roll and the second tank (although the respective structures of the second feed roll, the second tank roll and the second tank can differ from those of the first feed roll, the first tank roll and the first tank).

Similar to the discussion above with regard to the first applicator roll, by varying the thickness of the space between the second tank roll and the raised second pattern on the second applicator roll, the thickness of the second conductive ink applied to the semiconductor substrate can be finely controlled. In accordance with a preferred aspect of the present invention, a knob, lever or other thickness adjustment structure is provided, the movement of which causes either or both of the second tank roll and the second applicator roll to move so as to change the thickness of the space between the second tank roll and the raised second pattern on the second applicator roll. Preferably, there are further provided markings or some other gauge which is indicative of the extent of movement of the thickness adjustment structure, and therefore is indicative of the thickness of the space between the second tank roll and the raised second pattern on the second applicator roll. Accordingly, the thickness adjustment structure can be calibrated by comparison of the thickness adjustment structure gauge setting and the resulting thickness of the applied conductive ink. Using such calibration, the thickness of conductive ink applied to semiconductor substrates can be precisely controlled and readily varied, as desired.

It has been observed that where a PV cell comprises a semiconductor substrate formed of single crystal silicon and a contact comprising aluminum, the thickness of the aluminum contact has a direct effect on the resulting voltage of the current produced by the PV cell. Accordingly, this aspect of the invention can be of great importance in setting a spacing between an applicator roll and a feed roll which provides an aluminum contact having a thickness which maximizes the voltage of current produced by a PV cell.

Preferably, where the second conductive ink comprises aluminum, it is applied at a thickness of from about 28 μm to about 58 μm, and when dried, is of a thickness of from about 24 μm to about 48 μm. However, as mentioned above, the thickness applied can be varied within a wide range, e.g., the thickness can be as small as from about 1.3 μm to about 1.5 μm, or as large as about 150 μm. In comparison, as noted above, with a conventional screenprinting technique, it is typically not feasible to apply conductive ink in a thickness greater than about 25 μm.

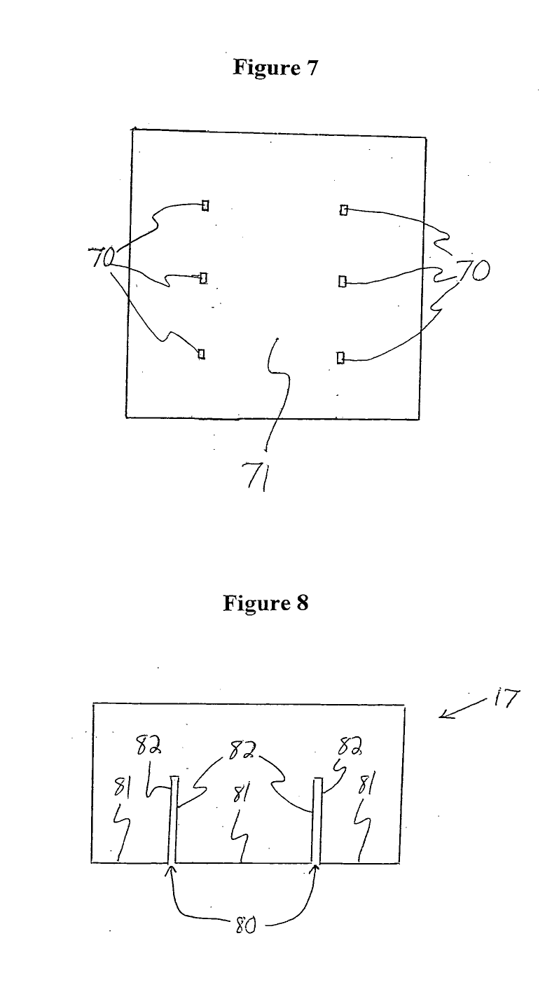

In this embodiment, the surface of the semiconductor substrate on which the first conductive ink and the second conductive ink have been applied has a pattern shown in FIG. 6, including two regions of silver 60 and three regions of aluminum 61. However, by tailoring the respective raised pattern surfaces of the rotatable applicator rolls, the surface of the semiconductor substrate on which the first conductive ink and the second conductive ink have been applied can be of any desired pattern. For example, the surface of the semiconductor substrate on which the first conductive ink and the second conductive ink have been applied can instead have a pattern, e.g., as shown in FIG. 7, including six regions of silver 70, the remainder of the surface of the semiconductor substrate being an aluminum region 71.

In this embodiment, the second conveyor conveys the semiconductor substrate from the second printing space through a second drying region and to a second surface printer. The second conveyor in this embodiment is generally similar to the first conveyor (and possible modifications) as described above, e.g., as shown in FIGS. 3 and 4, where the openings 23 are positioned within the second drying region at locations corresponding to where the second conductive ink has been applied. In this embodiment, where a larger surface area of conductive ink is applied in the second printing space (i.e., aluminum regions 61 in FIG. 6), there will be comparatively many more openings 23 than in the first drying region, and the pressure applied to the plenum 24 is preferably correspondingly greater in order to heat the regions where second printing ink has been applied. Also, the length of the second drying region and the speed of conveyance of the semiconductor substrate are preferably such that the second conductive ink is dry or substantially dry by the time the semiconductor substrate exits the second drying region.

In the present embodiment, the second conveyor conveys the semiconductor substrate from the second printing space, through the second drying region, and to a second surface printer, e.g., a conventional screenprinter.

In this embodiment, after the opposite surface of the semiconductor substrate is printed (e.g., screenprinted in a screenprinter), the semiconductor substrate is then conveyed by a third conveyor to a firing furnace.

Within the firing furnace, suitable firing conditions are maintained, and/or a suitable firing profile is carried out, suitable ranges for such conditions being well known. The semiconductor substrate is held in the firing furnace for a time period (taking into account the conditions within the firing furnace and the chemical nature of the materials printed on the semiconductor substrate), or subjected to a firing profile, such that the printed regions of the semiconductor substrate are fired. After being fired, the semiconductor substrate is conveyed out of the firing furnace and collected in a finished semiconductor substrate collector. A variety of structures which are suitable for use as such collectors are well known.

FIG. 8 is an overhead view of a scraper blade 17 which is suitable for use in the embodiment depicted in FIG. 1. Referring to FIG. 8, the scraper blade 17 includes a pair of slots 80 which accommodate the raised first pattern 18 of the first applicator roll 11 and a scraping edge 81 which scrapes conductive ink from circumferential portions of the tank roll 12 which are not adjacent to the circumferential surface of the raised first pattern 18 of the applicator roll 11. The slots 80 include side edges which scrape conductive ink from side portions of the raised first pattern 18.

If a doctor blade were positioned adjacent to the circumferential surface of the raised first pattern 18 of the applicator roll 11 in order to meter the amount of conductive ink present, a scraper blade would preferably be included so as to scrape any conductive ink which may be caused by the doctor blade to be moved to one of the sides of the raised first pattern of the applicator roll and/or to the circumferential surface of the applicator roll other than that of the raised first pattern.

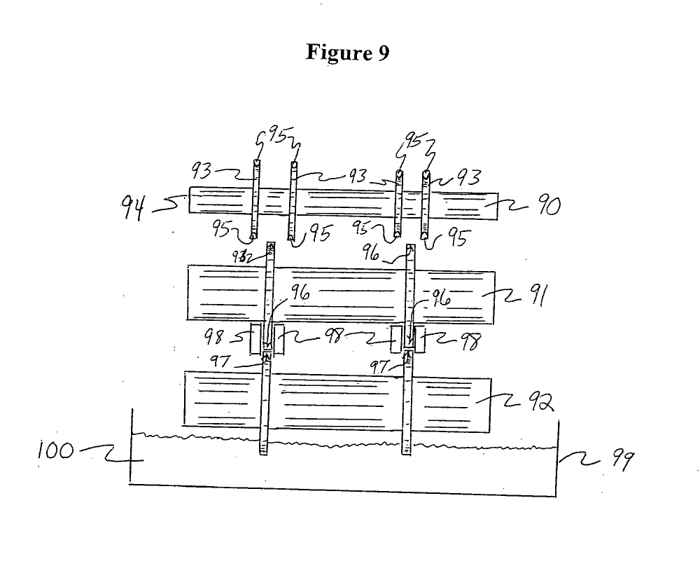

A modified embodiment of a system according to the present invention may include a feed roll 90, an applicator roll 91, a tank roll 92, and a tank 99 containing a conductive ink 100 as depicted in FIG. 9. In FIG. 9, the feed roll 90 comprises a stainless steel or aluminum cylindrical member 94 with four hubs 93, each hub 93 having a circumferential groove in which an O-ring 95 is positioned. Each of the hubs 93 is held in place on the member 94 with one or more tightening screws, which can, if desired, be loosened in order to re-locate the hubs 93 to any desired position along the member 94. In this modified embodiment, the tank roll 92 has raised outer surfaces 97 which, upon rotation of the tank roll 92 and the corresponding applicator roll 91, mirror the raised pattern surfaces 96 of the applicator roll 91. Such a modified embodiment assists in minimizing the amount of conductive ink which is applied to the applicator roll 91 in places other than on the raised pattern surfaces 96. Accordingly, instead of providing a scraper blade which scrapes conductive ink from circumferential portions of the tank roll 12 which are not adjacent to the circumferential surface of the raised first pattern 18 of the applicator roll 11, there can be provided a scraper (or scrapers) which scrape conductive ink from side portions of the raised first pattern 18 (e.g., such scrapers can include blocks 98 as shown in FIG. 9.

Although the methods and apparatus in accordance with the present invention have been described in connection with preferred embodiments, it will be appreciated by those skilled in the art that modifications not specifically described may be made without departing from the spirit and scope of the invention defined in the following claims. For example, any two or more structural parts of the apparatus can be integrated; any structural part of the apparatus can be provided in two or more parts.

1. An apparatus for applying at least one electrical contact to a semiconductor substrate, comprising:
at least first and second rotatable applicator rolls, said first rotatable applicator roll being rotatable about a first axis, said first rotatable applicator roll comprising a first roll printing surface, said first roll printing surface comprising at least one raised first pattern surface, each said raised first pattern surface being positioned such that upon rotation of said first rotatable applicator roll about said first axis, each said raised first pattern surface passes through a first printing space, whereby a first semiconductor substrate surface of a semiconductor substrate passing through said first printing space while said at least one raised first pattern surface is covered with a first conductive ink and said first rotatable applicator roll is being rotated will come into contact with said first conductive ink on at least a part of said raised first pattern surface, and will not come into contact with first conductive ink on substantially any of said first roll printing surface other than said raised first pattern surface, such that a first conductive ink pattern will be deposited on said first semiconductor substrate surface; and
at least a first conveyor which is operable to convey a semiconductor substrate to said second rotatable applicator roll after said semiconductor substrate passes through said first printing space,
said second rotatable applicator roll being rotatable about a second axis, said second rotatable applicator roll comprising a second roll printing surface, said second roll printing surface comprising at least one raised second pattern surface, each said raised second pattern surface being positioned such that upon rotation of said second rotatable applicator roll, each said raised second pattern surface passes through a second printing space, whereby said first semiconductor substrate surface of said semiconductor substrate passing through said second printing space while said raised second pattern surface is covered with a second conductive ink and second rotatable applicator roll is being rotated about said second axis will come into contact with said second conductive ink on at least part of said raised second pattern surface, and will not come into contact with second conductive ink on substantially any of said second roll printing surface other than said raised second pattern surface, such that a second conductive ink pattern will be deposited on said first semiconductor substrate surface.

2-47: (canceled)

48. A method for applying at least one electrical contact to a semiconductor substrate, comprising:
passing a semiconductor substrate through a first printing space;
rotating about a first axis a first applicator roll having a first roll printing surface which comprises at least one raised first pattern surface, such that each said raised first pattern surface passes through a first ink space containing a first conductive ink and through said first printing space, whereby said first conductive ink is passed from each said raised first pattern surface onto a first semiconductor substrate surface of said semiconductor substrate to deposit a first conductive ink pattern on said first semiconductor substrate surface;
conveying said semiconductor substrate from said first printing space to a second printing space;
passing said semiconductor substrate through said second printing space; and
rotating about a second axis a second applicator roll having a second roll printing surface which comprises at least one raised second pattern surface, such that each said raised second pattern surface passes through a second ink space containing a second conductive ink and through said second printing space, whereby said second conductive ink is passed from each said raised second pattern surface onto said first semiconductor substrate surface of said semiconductor substrate to deposit a second conductive ink pattern on said first semiconductor substrate surface.

49. A method as recited in claim 48, wherein at least one region of said first conductive ink pattern and at least one region of said second conductive ink pattern overlap by less than 1 cm.

50. A method as recited in claim 49, wherein said first conductive ink pattern and said second conductive ink pattern together cover substantially an entirety of said first semiconductor substrate surface, except for a border region around an edge of said first semiconductor substrate surface.

51. A method as recited in claim 49, wherein said first conductive ink pattern and said second conductive ink pattern together cover substantially an entirety of said first semiconductor substrate surface.

52. A method as recited in claim 48, further comprising:
rotating about a third axis a first tank roll having a first tank roll collection surface which passes through a first collection space positioned within a first conductive ink positioned within a first tank, and passes through said first ink space, whereby said first conductive ink is passed from said first tank to said first tank roll collection surface in said first collection space, and is passed from said first tank roll collection surface to said at least one raised first pattern surface in said first ink space; and
rotating about a fourth axis a second tank roll having a second tank roll collection surface which passes through a second collection space positioned within a second conductive ink positioned within a second tank, and passes through said second ink space, whereby said second conductive ink is passed from said second tank to said second tank roll collection surface in said second collection space, and is passed from said second tank roll collection surface to said at least one raised second pattern surface in said second ink space.

53. A method as recited in claim 48, further comprising:
rotating a first feed roll about a third axis, said first printing space being defined between said first applicator roll and said first feed roll; and
rotating a second feed roll about a fourth axis, said second printing space being defined between said second applicator roll and said second feed roll.

54. A method as recited in claim 48, further comprising drying said semiconductor substrate after said passing said semiconductor substrate through said first printing space and before said passing said semiconductor substrate through said second printing space.

55. (canceled)

56. (canceled)

57. A method as recited in claim 54, further comprising providing a second surface contact on a second semiconductor substrate surface of said semiconductor substrate.

58. (canceled)

59. (canceled)

60. A method as recited in claim 48, further comprising providing a second surface contact on a second semiconductor substrate surface of said semiconductor substrate.

61. (canceled)

62. A method as recited in claim 48, wherein said first conductive ink comprises from about 20 weight % to about 35 weight % of a solvent, about 2 weight % of a binder, from about 2 weight % to about 4 weight % aluminum, and the remainder silver.

63. A method as recited in claim 48, wherein said first conductive ink comprises a hot melt ink.

64. A method as recited in claim 63, wherein said first conductive ink comprises hexadecanol and silver.

65. A method as recited in claim 48, wherein said second conductive ink comprises from about 20 weight % to about 35 weight % of a solvent, about 2 weight % of a binder, and the remainder aluminum.

66. A method as recited in claim 48, wherein said second conductive ink comprises a hot melt ink.

67. A method as recited in claim 66, wherein said second conductive ink comprises hexadecanol and aluminum.

68. (canceled)

69. A method as recited in claim 48, wherein said semiconductor substrate comprises polycrystalline silicon.

70. A method as recited in claim 48, wherein said semiconductor substrate comprises single crystal silicon.

71. A method for applying at least one electrical contact to a semiconductor substrate, comprising:
passing a semiconductor substrate through a first printing space; and
rotating about a first axis a first applicator roll having a first roll printing surface which comprises at least one raised first pattern surface, such that each said raised first pattern surface passes through a first ink space containing a first conductive ink comprising a hot melt ink, and through said first printing space, whereby said first conductive ink is passed from at least one said raised first pattern surface onto a first semiconductor substrate surface of said semiconductor substrate to deposit a first conductive ink pattern on said first semiconductor substrate surface.

72. A method as recited in claim 71, wherein said first conductive ink comprises hexadecanol and silver.

73. (canceled)

74. (canceled)

75. A method as recited in claim 71, further comprising providing a second surface contact on a second semiconductor substrate surface of said semiconductor substrate.

76. A method as recited in claim 71, further comprising firing said semiconductor substrate after said providing said second surface contact.

77-79: (canceled)
